(19) United States
(12) Patent Application Publication
(10) Pub. No.: US 2024/0363337 A1
(43) Pub. Date: Oct. 31, 2024

(54) METHODS FOR FORMING LOW-K DIELECTRIC MATERIALS

(71) Applicant: Applied Materials, Inc., Santa Clara, CA (US)

(72) Inventors: Muthukumar Kaliappan, Fremont, CA (US); Bo Xie, San Jose, CA (US); Shanshan Yao, San Jose, CA (US); Li-Qun Xia, Cupertino, CA (US); Michael Haverty, Mountain View, CA (US); Rui Lu, Santa Clara, CA (US); Xiaobo Li, San Jose, CA (US); Chi-I Lang, Cupertino, CA (US); Shankar Venkataraman, San Jose, CA (US)

(73) Assignee: Applied Materials, Inc., Santa Clara, CA (US)

(21) Appl. No.: 18/139,699

(22) Filed: Apr. 26, 2023

(51) Int. Cl. H01L 21/02; C23C 16/32; C23C 16/455; C23C 16/56

(52) U.S. Cl. CPC H01L 21/02167; C23C 16/325; C23C 16/45542; C23C 16/45553; C23C 16/45565; C23C 16/56; H01L 21/02211; H01L 21/02274

(57) ABSTRACT

Semiconductor processing methods are described for forming low-κ dielectric materials. The methods may include providing deposition precursors to a processing region of a semiconductor processing chamber. The deposition precursors may include a silicon-carbon-and-hydrogen-containing precursor. A substrate may be disposed within the processing region. The methods may include forming plasma effluents of the deposition precursors. The methods may include depositing a layer of silicon-containing material on the substrate. The layer of silicon-containing material may be characterized by a dielectric constant of less than or about 4.0.

### TECHNICAL FIELD

The present technology relates to deposition processes and chambers. More specifically, the present technology relates to methods of producing low-κ materials.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the materials are removed relative to one another. Plasma-enhanced deposition may produce materials having certain characteristics, which may affect the performance of the device. The characteristics of the material may be adjusted or enhanced by modifying the deposition conditions, such as the chemistry and frequency of the plasma.

Thus, there is a need for improved systems and methods that can be used to produce high quality devices and structures. These and other needs are addressed by the present technology.

### SUMMARY

Embodiments of the present technology include semiconductor processing methods that may form low-κ dielectric materials. The methods may include providing deposition precursors to a processing region of a semiconductor processing chamber. The deposition precursors may include a silicon-carbon-and-hydrogen-containing precursor. A substrate may be disposed within the processing region. The methods may include forming plasma effluents of the deposition precursors. The methods may include depositing a layer of silicon-containing material on the substrate. The layer of silicon-containing material may be characterized by a dielectric constant of less than or about 4.0.

In some embodiments, the silicon-carbon-and-hydrogen-containing precursor may be or include bis(trimethylsilyl) methane or 1,1,3,3-tetramethyl-1,3-disilacyclobutane. The silicon-carbon-and-hydrogen-containing precursor may further include oxygen. The silicon-carbon-and-hydrogen-containing precursor may be or include dimethyldimethoxysilane, 1,1,3,3-tetramethyl-1,3-dimethoxydisiloxane, or methoxy (dimethyl) silylmethane. The deposition precursors may further include a boron-containing precursor, a nitrogen-containing precursor, or both. The boron-containing precursor may be or include diborane (B₂H₆). The layer of silicon-containing material may be characterized by a thickness of less than or about 50 Å. The layer of silicon-containing material may be characterized by a density of greater than or about 2.50 g/cm³. The layer of silicon-containing material may be deposited at a rate of greater than or about 200 Å/min. The methods may include exposing the layer of silicon-containing material to ultraviolet light to provide a cured layer of silicon-containing material. The cured layer of silicon-containing material may be characterized by a stress of less than or about-150 MPa.

Some embodiments of the present technology may encompass semiconductor processing methods. The methods may include providing deposition precursors to a processing region of a semiconductor processing chamber. The deposition precursors may include a silicon-containing precursor and a dopant-containing precursor. A substrate may be disposed within the processing region. The methods may include forming plasma effluents of the deposition precursors. The methods may include depositing a layer of silicon-containing material on the substrate. The layer of silicon-containing material may be characterized by a dielectric constant of less than or about 4.0. The layer of silicon-containing material may be characterized by a density of greater than or about 2.30 g/cm³.

In some embodiments, the silicon-containing precursor may include a silicon-carbon-and-hydrogen-containing precursor or a silicon-oxygen-carbon-and-hydrogen-containing precursor. The dopant precursor may be a boron-containing precursor. A flow rate of the dopant precursor may be less than or about 1,000 sccm. The layer of silicon-containing material may be characterized by a breakdown voltage of greater than or about 6.0 MV/cm. The layer of silicon-containing material may be characterized by a dielectric constant of less than or about 3.3. A temperature within the processing region may be maintained at less than or about 500° C.

Some embodiments of the present technology may encompass semiconductor processing methods. The methods may include providing deposition precursors to a processing region of a semiconductor processing chamber. The deposition precursors may include a silicon-containing precursor and a boron-containing precursor. A substrate may be disposed within the processing region. The methods may include forming plasma effluents of the deposition precursors. The methods may include depositing a layer of silicon-containing material on the substrate. The layer of silicon-containing material may be characterized by a dielectric constant of less than or about 3.5. The layer of silicon-containing material is characterized by a density of greater than or about 2.50 g/cm³.

In some embodiments, the methods may include exposing the layer of silicon-containing material to ultraviolet light to provide a cured layer of silicon-containing material. The layer of silicon-containing material may be characterized by a boron concentration of less than or about 20.0 at. %.

Such technology may provide numerous benefits over conventional processing methods. For example, utilizing silicon-containing precursors that include oxygen, carbon, and/or hydrogen may modify atomic structure of the material to reduce dielectric constant of the material without impacting mechanical characteristics, such as density. Additionally, incorporating a dopant precursor may further modify atomic structure of the material to reduce dielectric constant of the material without impacting mechanical characteristics. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During back-end-of-line (BEOL) semiconductor processing, low-κ materials may serve multiple functions in the fabrication of metallization layers in an integrated circuit. These functions may include the incorporation of electrically-insulating low-κ materials between electrically-conductive metal-containing structures such as interconnect lines, contact holes, and vias, among other structures. They may also include the partial removal of a low-κ material following the formation of metal structure. One common removal process in BEOL processing is chemical-mechanical-polishing (CMP) that uses a combination of chemical etching and physical abrasion to remove the low-κ material from a substrate surface.

Low-κ materials used in BEOL processing should have a low dielectric constant (κ value) relative to undoped silicon oxide and high mechanical stability to resist fracturing during the formation of metal-containing structures and removal by CMP. Unfortunately, these qualities are often in tension in low-κ materials. In many instances, the deposition and treatment operations increase the porosity of the material, and the increased porosity can reduce the mechanical stability of the material. In addition, the increased levels of carbon in the material may both lower the κ value and reduce the mechanical stability of the material. The reduction in mechanical stability may be measured by the material having a lower density, among the other mechanical characteristics of the material.

The present technology may overcome these issues by including embodiments of semiconductor processing methods that form low-κ materials with good mechanical stability. In embodiments, these low-κ materials may be formed by using certain precursors to modify the atomic structure of the deposited material. The present technology may provide silicon-containing low-κ materials characterized by a low dielectric constant (κ value) of less than or about 4.0. Additionally, embodiments of the present method maintain the mechanical stability of the materials the low dielectric constant (κ value). The materials may be characterized by a density of greater than or about 2.30 g/cm³. Additionally, in some embodiments, an ultraviolet (UV) treatment may be performed to further increase desired properties of the material.

Although the remaining disclosure will routinely identify specific deposition processes utilizing the disclosed technology, it will be readily understood that the systems and methods are equally applicable to other deposition chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

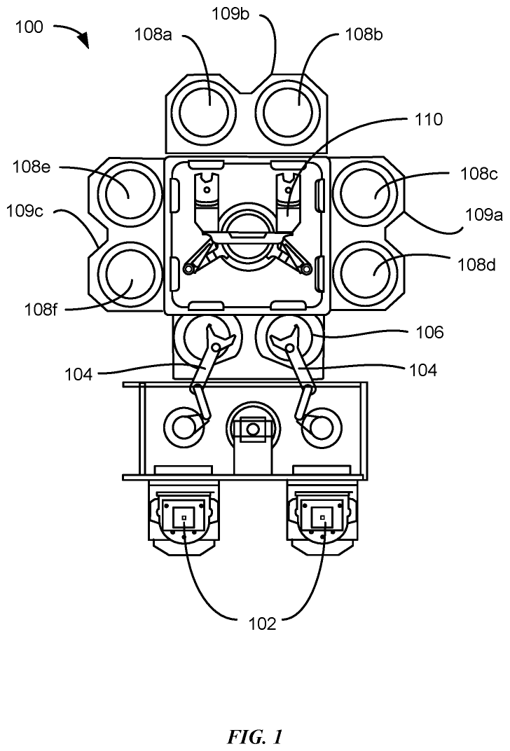

FIG. 1 shows a top plan view of one embodiment of a processing system 100 of deposition, etching, baking, and UV treatment chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including plasma-enhanced chemical vapor deposition, atomic layer deposition, physical vapor deposition, etch, UV treatments, pre-clean, degas, orientation, and other substrate processes including, annealing, ashing, etc.

The substrate processing chambers 108a-f may include one or more system components for depositing, annealing, UV treating and/or etching a dielectric or other material on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric materials on the substrate. Any one or more of the processes described may be carried out in chambers separated from the fabrication system shown in different embodiments. It will be appreciated that additional configurations of deposition, etching, annealing, and UV treatment chambers for dielectric materials are contemplated by system 100.

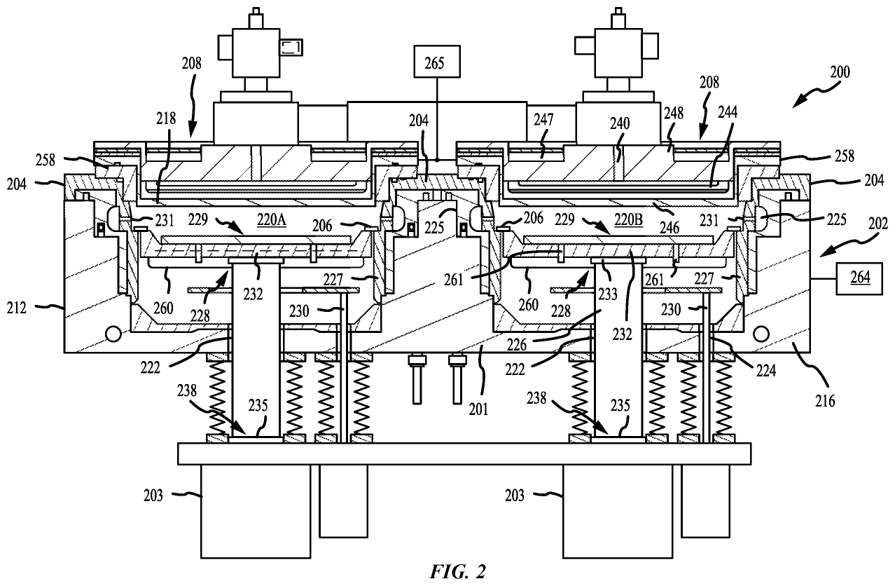

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. The dual-channel showerhead 218 and/or faceplate 246 may include one or more openings to permit the flow of precursors from the precursor distribution system 208 to the processing regions 220A and/or 220B. In some embodiments, the openings may include at least one of straight-shaped openings and conical-shaped openings. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

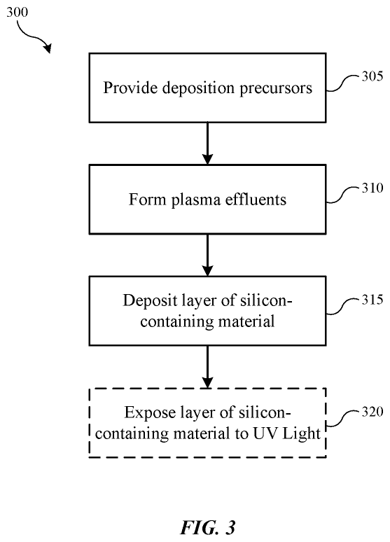

FIG. 3 shows operations of an exemplary method 300 of semiconductor processing according to some embodiments of the present technology. The method may be performed in a variety of processing chambers, including processing system 200 described above, as well as any other chamber in which plasma deposition may be performed. Method 300 may include a number of optional operations, which may or may not be specifically associated with some embodiments of methods according to the present technology.

Method 300 may include plasma-enhanced chemical-vapor-deposition (PECVD) processing operations to form as-deposited, low-κ materials. The method 300 may include optional operations prior to initiation of method 300, or the method 300 may include additional operations after the deposition of the low-κ material, such as a UV treatment of the low-κ material. In embodiments, method 300, as shown in FIG. 3, may include providing deposition precursors into a processing region of a semiconductor processing chamber at operation 305. A substrate may be housed in the processing region of the semiconductor processing chamber as the deposition precursors are provided into the chamber.

In some embodiments, the deposition precursors may include a silicon-containing precursor. Silicon-containing precursors that may be used may be or include, but are not limited to, silane (SiH₄), disilane (Si₂H₆), or tetraethyl orthosilicate (TEOS). In embodiments, the silicon-containing precursor may further include carbon and hydrogen. Specific silicon-carbon-and-hydrogen-containing precursors may be or include, but are not limited to, bis(trimethylsilyl) methane or 1,1,3,3-tetramethyl-1,3-disilacyclobutane. Some silicon-containing precursors may further include oxygen, carbon, and hydrogen. For example, specific silicon-oxygen-carbon-and-hydrogen-containing precursors may be or include, but are not limited to, dimethyldimethoxysilane, 1,1,3,3-tetramethyl-1,3-dimethoxydisiloxane, or methoxy (dimethyl) silylmethane.

The deposition precursors may further include one or more dopant precursors, such as a boron-containing precursor. Boron-containing precursors that may be used may include, but are not limited to, borane (BH₃), diborane (B₂H₆), trimethyl boron ((CH₃)₃B), as well as any other boron-containing precursors that may be used in boron-doped silicon-containing material formation. In embodiments, the flow rate of the boron-containing precursor relative to the flow rate of the silicon-containing precursor may be maintained at a flow rate ratio that assists in forming a low-κ materials with both a low dielectric constant (κ value) and high mechanical stability as reflected in material characteristics such as refractive index and density, among others. In embodiments, a flow rate ratio for the boron-containing precursor relative to the silicon-containing precursor may be less than or about 1:5, less than or about 1:6, less than or about 1:7, less than or about 1:8, less than or about 1:9, less than or about 1:10, or less.

By utilizing silicon-containing precursors including oxygen, carbon, and/or hydrogen, such as the specific precursors previously listed, as well as boron-containing precursors, various Si—N, C—N, Si—B, and C—B bonds may be formed to lower the dielectric constant of the material. The deposition precursors may also include one or more carrier gases such as helium, argon, and nitrogen (N₂). Although the one or more carrier gases may be delivered with other deposition precursors, the carrier gases may be considered inert gases that do not react to form part of the as-deposited material. The one or more carrier gases may be delivered with other deposition precursors to serve as a diluent.

A flow rate for the silicon-containing precursor may be greater than or about 100 sccm, greater than or about 125 sccm, greater than or about 150 sccm, greater than or about 175 sccm, greater than or about 200 sccm, greater than or about 250 sccm, greater than or about 300 sccm, greater than or about 400 sccm, greater than or about 500 sccm, or more. A flow rate for the boron-containing precursor may be greater than or about 5 sccm, greater than or about 10 sccm, greater than or about 15 sccm, greater than or about 20 sccm, greater than or about 25 sccm, greater than or about 30 sccm, greater than or about 35 sccm, greater than or about 40 sccm, greater than or about 45 sccm, greater than or about 50 sccm, greater than or about 55 sccm, greater than or about 60 sccm, greater than or about 65 sccm, greater than or about 70 sccm, greater than or about 75 sccm, greater than or about 80 sccm, greater than or about 90 sccm, greater than or about 100 sccm, or more. The flow rate of the boron-containing precursor may also be less than or about 1,250 sccm, less than or about 1,000 sccm, less than or about 750 sccm, less than or about 500 sccm, less than or about 400 sccm, less than or about 300 sccm, or less. A flow rate for the one or more carrier gases may be greater than or about 200 sccm, greater than or about 300 sccm, greater than or about 400 sccm, greater than or about 500 sccm, greater than or about 750 sccm, greater than or about 1,000 sccm, greater than or about 2,000 sccm, greater than or about 3,000 sccm, greater than or about 3,000 sccm, greater than or about 4,000 sccm, greater than or about 5,000 sccm, or more. The flow rate of the combined deposition precursors may be greater than or about 250 sccm, greater than or about 500 sccm, greater than or about 750 sccm, greater than or about 1,000 sccm, greater than or about 2,500 sccm, greater than or about 5,000 sccm, or more.

In embodiments, the deposition precursors provided to the processing region of the semiconductor processing chamber may alter the pressure in the chamber. During method 300, a pressure in the semiconductor processing chamber may be greater than or about 1 Torr, greater than or about 2 Torr, greater than or about 3 Torr, greater than or about 4 Torr, greater than or about 5 Torr, greater than or about 6 Torr, greater than or about 7 Torr, greater than or about 8 Torr, greater than or about 9 Torr, greater than or about 10 Torr, or more.

Embodiments of method 300 may include forming plasma effluents from the deposition precursors at operation 310. The plasma effluents may be generated from the deposition precursors within the processing region, such as by providing RF power to the faceplate to generate a plasma within the processing region of the semiconductor processing chamber. The plasma effluents may be generated at any of the frequencies previously described, and may be generated at a frequency less than 15 MHz (e.g., 13.56 MHz). Although higher frequency may be used, lower frequency plasma generation may facilitate removal of carbon during processing, unlike higher plasma frequency operations.

Embodiments of method 300 may include depositing a silicon-containing material on the substrate at operation 315. As previously discussed, the substrate may be present in the processing region of the semiconductor processing chamber, and the silicon-containing material may be formed from plasma effluents generated by the deposition plasma also present in the processing region. The processing region and, therefore, the substrate may be characterized by a temperature less than or about 600° C., less than or about 580° C., less than or about 560° C., less than or about 540° C., less than or about 520° C., less than or about 500° C., less than or about 480° C., less than or about 460° C., less than or about 440° C., less than or about 420° C., less than or about 400° C., less than or about 380° C., less than or about 360° C., less than or about 340° C., less than or about 320° C., less than or about 300° C., or less during the deposition.

When a dopant precursor, such as a boron-containing precursor is provided, dopant concentration in the material may be controlled based on the flow rate of the precursor. For example, a boron concentration in the material may be less than or about 20.0 at. %, and may be less than or about 19.0 at. %, less than or about 18.0 at. %, less than or about 17.0 at. %, less than or about 16.0 at. %, less than or about 15.0 at. %, less than or about 14.0 at. %, less than or about 13.0 at. %, less than or about 12.0 at. %, less than or about 11.0 at. %, less than or about 10.0 at. %, less than or about 9.0 at. %, less than or about 8.0 at. %, less than or about 7.0 at. %, less than or about 6.0 at. %, less than or about 5.0 at. %, less than or about 4.0 at. %, less than or about 3.0 at. %, or less.

As explained above, the methods of the present technology include embodiments that utilize deposition precursors and processing conditions that form low-κ materials having a low dielectric constant and high mechanical stability. In embodiments of method 300, as-deposited low-κ materials may be formed as silicon-containing materials with dielectric constants less than or about 4.0, less than or about 3.9, less than or about 3.8, less than or about 3.7, less than or about 3.6, less than or about 3.5, less than or about 3.4, less than or about 3.3, less than or about 3.2, less than or about 3.1, less than or about 3.0, less than or about 2.9, less than or about 2.8, less than or about 2.7, less than or about 2.6, less than or about 2.5, or less. In embodiments, the density of the formed materials may be greater than or about 2.30 g/cm³, greater than or about 2.40 g/cm³, greater than or about 2.50 g/cm³, greater than or about 2.55 g/cm³, greater than or about 2.60 g/cm³, greater than or about 2.65 g/cm³, greater than or about 2.70 g/cm³, greater than or about 2.75 g/cm³, greater than or about 2.80 g/cm³, greater than or about 2.85 g/cm³, greater than or about 2.90 g/cm³, or greater.

Based on the deposition precursors used, more high compressive materials may be deposited. Low stress materials may be characterized by internal stress levels that are closer to neutral stress (i.e., 0 MPa). In contrast, high stress materials are characterized by internal stress levels that are significantly greater than 0 MPa (i.e., high positive (tensile) stress) or significantly less than 0 MPa (i.e., high negative (compressive) stress). High positive stress, which may be characterized as tensile stress, may be caused by the expansion of the material that creates an outward, pushing force on adjacent substrate features. High negative stress, which may be characterized as compressive stress, may be caused by the contraction of the material that creates an inward, pulling force on adjacent substrate features. In other words, higher-stress materials may be characterized by a stress level with an absolute value that is significantly greater than 0 MPa. Thus, when a material is characterized by a stress level of “greater than −1,000 MPa”, this refers to the absolute value of the stress level, and includes levels such as −1500 MPa, −2000 MPa, etc. Similarly, when a material is characterized by a stress level of “less than −1,000 MPa”, this refers stress levels that are closer to neutral stress (i.e., 0 MPa), and includes levels such as −500 MPa, −100 MPa, etc., but does not extend to positive values greater than or about 1,000 MPa. For example, when the deposition precursors including a boron-containing precursor, increased flow rates of the boron-containing precursor may result in a more compressive material being deposited. In embodiments, the as-deposited materials may be characterized by a stress of greater than or about −150 MPa, and may be characterized by a stress of greater than or about −175 MPa, greater than or about −200 MPa, greater than or about −225 MPa, greater than or about −250 MPa, greater than or about −275 MPa, greater than or about −300 MPa, greater than or about −325 MPa, greater than or about −350 MPa, greater than or about −375 MPa, greater than or about −400 MPa, or greater. In embodiments, stress may increase with increased flow rates of the boron-containing precursor.

Additionally, refractive index of the as-deposited materials may increase with increased flow rates of the boron-containing precursor. Refractive index may be an indication of film composition, with increased refractive index being correlated with higher density material. In embodiments, the refractive index of the as-deposited materials may be greater than or about 1.70, greater than or about 1.75, greater than or about 1.80, greater than or about 1.82, greater than or about 1.84, greater than or about 1.85, greater than or about 1.86, greater than or about 1.87, greater than or about 1.88, greater than or about 1.89, greater than or about 1.90, or greater.

Materials according to embodiments of the present technology may be characterized by breakdown voltage of greater than or about 5.8 MV/cm, and may be characterized by breakdown voltage of greater than or about 5.9 MV/cm, greater than or about 6.0 MV/cm, greater than or about 6.1 MV/cm, greater than or about 6.2 MV/cm, greater than or about 6.3 MV/cm, greater than or about 6.4 MV/cm, greater than or about 6.5 MV/cm, greater than or about 6.6 MV/cm, greater than or about 6.7 MV/cm, greater than or about 6.8 MV/cm, greater than or about 6.9 MV/cm, greater than or about 7.0 MV/cm, greater than or about 7.1 MV/cm, greater than or about 7.2 MV/cm, or greater. Increased flow rates of the boron-containing precursor and, therefore, increased boron concentration in the materials may decrease breakdown voltage.

Increased boron concentration may result in more B—N bonding in the material, which may degrade breakdown voltage.

Depending on flow rates of the deposition precursors, the delta stress of the as-deposited material may be less than or about 400 MPa. At certain boron-containing precursor flow rates, such as greater than or about 25 sccm, for example, the delta stress may reach an upper limit. Additionally, increased flow rate of a nitrogen-containing precursor may also increase delta stress. By tuning flow rates of the deposition precursors, delta stress of the as-deposited material may be maintained less than or about 400 MPa. For example, the delta stress may be less than or about 375 MPa, less than or about 350 MPa, less than or about 325 MPa, less than or about 300 MPa, less than or about 275 MPa, less than or about 250 MPa, less than or about 225 MPa, less than or about 200 MPa, less than or about 175 MPa, or less. Lower delta stress values may be correlated with better hermeticity of the material.

Embodiments of the method 300 may further include exposing the as-deposited silicon-and-carbon-containing material to an ultraviolet (UV) treatment at optional operation 320. In embodiments, the UV treatment may be performed in the semiconductor processing chamber used for the deposition of the low-κ material. However, it is also contemplated that the substrate with the as-deposited low-κ material may be transferred to another semiconductor processing chamber where the UV treatment operation is performed. In embodiments, the UV treatment at optional operation 320 may expose the layer of silicon-containing material to ultraviolet light to provide a cured layer of silicon-containing material. The treatment may produce a cured low-κ material characterized by an increased porosity and/or lower dielectric constant (κ value) than the as-deposited material. The increased porosity of the cured low-κ material may decrease the dielectric constant of the material to less than or about 3.5, less than or about 3.4, less than or about 3.3, less than or about 3.2, less than or about 3.1, less than or about 3.0, less than or about 2.9, less than or about 2.8, less than or about 2.7, less than or about 2.6, or less.

Subsequent the UV treatment, the cured material may be characterized by a reduced stress compared to the as-deposited material. In embodiments, the cured layer of silicon-containing material is characterized by a stress of less than or about −200 MPa, and may be characterized by a stress of less than or about −175 MPa, less than or about −150 MPa, less than or about −125 MPa, less than or about −100 MPa, less than or about −75 MPa, less than or about −50 MPa, less than or about −25 MPa, or less.

The deposition rate for the as-deposited silicon-containing material may exceed 200 Å/min, and may be deposited at a rate greater than or about 225 Å/min, greater than or about 250 Å/min, greater than or about 275 Å/min, greater than or about 300 Å/min, greater than or about 325 Å/min, greater than or about 350 Å/min, greater than or about 375 Å/min, greater than or about 400 Å/min, or more. The as-deposited silicon-containing material may be deposited to a thickness of greater than or about 10 Å, greater than or about 15 Å, greater than or about 20 Å, greater than or about 25 Å, greater than or about 30 Å, greater than or about 35 Å, greater than or about 40 Å, greater than or about 45 Å, greater than or about 50 Å, or more. In some embodiments, the as-deposited silicon-containing material may be deposited to a thickness of less than or about 50 Å, less than or about 45 Å, less than or about 40 Å, less than or about 35 Å, less than or about 30 Å, less than or about 25 Å, less than or about 20 Å, less than or about 15 Å, less than or about 10 Å, or less. The as-deposited silicon-containing material may be deposited in two or more deposition and UV-treatment cycles to build up the final, UV-treated, low-κ material. For example, the number of deposition and treatment cycles may be greater than or about three cycles, greater than or about five cycles, greater than or about ten cycles, greater than or about 15 cycles, greater than or about 20 cycles, greater than or about 30 cycles, greater than or about 40 cycles, greater than or about 50 cycles, or more.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layer, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing deposition precursors to a processing region of a semiconductor processing chamber, wherein the deposition precursors comprise a silicon-carbon-and-hydrogen-containing precursor, wherein a substrate is disposed within the processing region;
forming plasma effluents of the deposition precursors; and
depositing a layer of silicon-containing material on the substrate, wherein the layer of silicon-containing material is characterized by a dielectric constant of less than or about 4.0.

2. The semiconductor processing method of claim 1, wherein the silicon-carbon-and-hydrogen-containing precursor comprises bis(trimethylsilyl) methane or 1,1,3,3-tetramethyl-1,3-disilacyclobutane.

3. The semiconductor processing method of claim 1, wherein the silicon-carbon-and-hydrogen-containing precursor further comprises oxygen.

4. The semiconductor processing method of claim 3, wherein the silicon-carbon-and-hydrogen-containing precursor comprises dimethyldimethoxysilane, 1,1,3,3-tetramethyl-1,3-dimethoxydisiloxane, or methoxy (dimethyl) silylmethane.

5. The semiconductor processing method of claim 1, wherein the deposition precursors further comprise a boron-containing precursor, a nitrogen-containing precursor, or both.

6. The semiconductor processing method of claim 5, wherein the boron-containing precursor comprises diborane (B₂H₆).

7. The semiconductor processing method of claim 1, wherein the layer of silicon-containing material is characterized by a thickness of less than or about 50 Å.

8. The semiconductor processing method of claim 1, wherein the layer of silicon-containing material is characterized by a density of greater than or about 2.50 g/cm³.

9. The semiconductor processing method of claim 1, wherein the layer of silicon-containing material is deposited at a rate of greater than or about 200 Å/min.

10. The semiconductor processing method of claim 1, further comprising:
exposing the layer of silicon-containing material to ultraviolet light to provide a cured layer of silicon-containing material, wherein the cured layer of silicon-containing material is characterized by a stress of less than or about −150 MPa.

11. A semiconductor processing method comprising:
providing deposition precursors to a processing region of a semiconductor processing chamber, wherein the deposition precursors comprise a silicon-containing precursor and a dopant-containing precursor, wherein a substrate is disposed within the processing region;
forming plasma effluents of the deposition precursors; and
depositing a layer of silicon-containing material on the substrate, wherein the layer of silicon-containing material is characterized by a dielectric constant of less than or about 4.0, and wherein the layer of silicon-containing material is characterized by a density of greater than or about 2.30 g/cm³.

12. The semiconductor processing method of claim 11, wherein the silicon-containing precursor comprises a silicon-carbon-and-hydrogen-containing precursor or a silicon-oxygen-carbon-and-hydrogen-containing precursor.

13. The semiconductor processing method of claim 11, wherein the dopant precursor comprises a boron-containing precursor.

14. The semiconductor processing method of claim 11, wherein a flow rate of the dopant precursor is less than or about 1,000 sccm.

15. The semiconductor processing method of claim 11, wherein the layer of silicon-containing material is characterized by a breakdown voltage of greater than or about 6.0 MV/cm.

16. The semiconductor processing method of claim 11, wherein the layer of silicon-containing material is characterized by a dielectric constant of less than or about 3.3.

17. The semiconductor processing method of claim 11, wherein a temperature within the processing region is maintained at less than or about 500° C.

18. A semiconductor processing method comprising:
providing deposition precursors to a processing region of a semiconductor processing chamber, wherein the deposition precursors comprise a silicon-containing precursor and a boron-containing precursor, wherein a substrate is disposed within the processing region;
forming plasma effluents of the deposition precursors; and
depositing a layer of silicon-containing material on the substrate, wherein the layer of silicon-containing material is characterized by a dielectric constant of less than or about 3.5, and wherein the layer of silicon-containing material is characterized by a density of greater than or about 2.50 g/cm³.

19. The semiconductor processing method of claim 18, further comprising:
exposing the layer of silicon-containing material to ultraviolet light to provide a cured layer of silicon-containing material.

20. The semiconductor processing method of claim 18, wherein the layer of silicon-containing material is characterized by a boron concentration of less than or about 20.0 at. %.
